(19) United States
(12) Patent Application Publication
(10) Pub. No.: US 2026/0254410 A1
(43) Pub. Date: Aug. 27, 2026

(54) OSCILLATOR CIRCUITS HAVING DELTA-SIGMA MODULATED INJECTION

(71) Applicant: SKYWORKS SOLUTIONS, INC., Irvine, CA (US)

(72) Inventors: Praveen Kumar VENKATACHALA, Portland, OR (US); Wai Laing LEE, Portland, OR (US); Dipan KAR, Pullman, WA (US)

(21) Appl. No.: 19/533,145

(22) Filed: Feb. 7, 2026

Related U.S. Application Data
(60) Provisional application No. 63/756,027, filed on Feb. 7, 2025.

(51) Int. Cl. H03B 5/36; H03M 3/00

(52) U.S. Cl. CPC H03B 5/36; H03M 3/38

(57) ABSTRACT

An oscillator circuit can include an oscillator configured to provide an output signal having a frequency based on a first oscillation signal having a frequency. The oscillator circuit can further include a digital calibration circuit configured to inject a calibration signal to the oscillator during a startup process to allow the frequency of the output signal to be established at a desired frequency. The digital calibration circuit can include a delta-sigma modulator configured to generate the calibration signal based on a digital control word.

### CROSS-REFERENCE TO RELATED APPLICATION(S)

This application claims priority to U.S. Provisional Application No. 63/756,027 filed Feb. 7, 2025, entitled OSCILLATOR CIRCUITS HAVING DELTA-SIGMA MODULATED INJECTION, the disclosure of which is hereby expressly incorporated by reference herein in its entirety.

### BACKGROUND

### Field

The present disclosure relates to oscillator circuits for electronic applications.

### Description of the Related Art

In many electronic applications, use of an oscillating signal having an accurate frequency is desirable. Such an oscillating signal is typically provided by an oscillator circuit the includes, for example, an oscillator such as a crystal oscillator.

### SUMMARY

In accordance with a number of implementations, the present disclosure relates to an oscillator circuit that includes an oscillator configured to provide an output signal having a frequency based on a first oscillation signal having a frequency. The oscillator circuit further includes a digital calibration circuit configured to inject a calibration signal to the oscillator during a startup process to allow the frequency of the output signal to be established at a desired frequency, with the digital calibration circuit including a delta-sigma modulator configured to generate the calibration signal based on a digital control word.

In some embodiments, the digital calibration circuit can include a waveform that includes components of the desired frequency. The desired frequency can include the frequency of the first oscillation signal.

In some embodiments, the digital calibration circuit can include a digital word calibration block configured to generate an N-bit word as the digital control word based on the frequency of the first oscillation signal and a frequency of a second oscillation signal. The first oscillation signal can be provided by a crystal oscillation source, and the second oscillation signal can be provided by a ring oscillator. The frequency of the second oscillation signal can be greater than the frequency of the first oscillation signal. The frequency of the second oscillation signal can be M times the frequency of the first oscillation signal, with M being a positive integer greater than 1.

In some embodiments, the N-bit word can include a 16-bit word. In some embodiments, the delta-sigma modulator can be configured to generate the calibration signal based on the N-bit word provided by the digital word calibration block. In some embodiments, the oscillator circuit can further include a switch network configured allow the calibration signal to be injected to the oscillator in a selected manner.

In some embodiments, the oscillator circuit can further include a source of the first oscillation signal and/or a source of the second oscillation signal. Each of the first oscillation signal and the second oscillation signal can be a part of the oscillator circuit.

In some implementations, the present disclosure relates to a method for operating an oscillator circuit. The method includes receiving a first oscillation signal having a frequency, and operating an oscillator to provide an output signal having a frequency based on the first oscillation signal. The method further includes providing a calibration signal to the oscillator during a startup of the oscillation circuit to allow the frequency of the output signal to be established at a desired frequency, with the calibration signal including a delta-sigma modulated signal based on a digital word.

In some embodiments, the digital word can include an N-bit word based on the frequency of the first oscillation signal and a frequency of a second oscillation signal. The frequency of the second oscillation signal can be greater than the frequency of the first oscillation signal. The frequency of the second oscillation signal can be M times the frequency of the first oscillation signal, with M being a positive integer greater than 1.

In some embodiments, the N-bit word can include a 16-bit word.

In some embodiments, the method can further include performing a switching operation to inject the calibration signal to the oscillator in a selected manner.

In some implementations, the present disclosure relates to an electronic chip that includes a substrate and an integrated circuit that includes an oscillator circuit. The oscillator circuit includes an oscillator configured to provide an output signal having a frequency based on a first oscillation signal having a frequency. The oscillator circuit further includes a digital calibration circuit configured to inject a calibration signal to the oscillator during a startup process to allow the frequency of the output signal to be established at a desired frequency, with the digital calibration circuit including a delta-sigma modulator configured to generate the calibration signal based on a digital control word.

In some embodiments, the electronic chip can be implemented as a semiconductor die such as a CMOS process die.

In some implementations, the present disclosure relates to an electronic device that includes a functional circuit and an oscillator circuit configured to allow operation of the functional circuit. The oscillator circuit includes an oscillator configured to provide an output signal having a frequency based on a first oscillation signal having a frequency. The oscillator circuit further includes a digital calibration circuit configured to inject a calibration signal to the oscillator during a startup process to allow the frequency of the output signal to be established at a desired frequency, with the digital calibration circuit including a delta-sigma modulator configured to generate the calibration signal based on a digital control word.

In some embodiments, the functional circuit can be configured to include a wireless functionality. In some embodiments, the electronic device can be an IoT device.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts an oscillator circuit configured to provide an output signal having an output frequency.

FIG. 2 shows an architecture that can be implemented as a more specific example of the oscillator circuit of FIG. 1.

FIG. 3 shows various example timing diagrams associated with the architecture of FIG. 2.

FIG. 4 shows an example timing diagram during a power on process.

FIG. 5 shows an example time duration of re-calibration of frequency control word (FCW).

FIG. 6 shows a first-order delta-sigma modulator (DSM) configuration and its corresponding equivalent error-feedback model for the calibration control architecture 100 of FIG. 2.

FIG. 7 shows a block diagram of an FCW generator that can be implemented for the Digital FCW Calibration block of FIG. 2.

FIG. 8 shows an example of a DSM-based injection signal generator that can be implemented for the DSM block of FIG. 2.

FIG. 9 shows a simulated output of an arithmetic divider of FIG. 7.

FIG. 10 shows a startup waveform achieved with the DSM-based injection technique as described herein.

FIG. 11 shows a typical measured crystal oscillator startup waveform with no injection.

FIG. 12 shows an example startup time across supply voltage variation.

FIG. 13 shows an example where startup time measurements are obtained across 20° C.-85° C.

FIG. 14 shows an example chip on which the architecture of FIG. 2 was implemented.

FIG. 15 shows a table with various parameters and performance values in comparison with other startup techniques mentioned herein.

FIG. 16 shows that in some embodiments, an oscillator circuit having one or more features as described herein can be implemented on a chip.

FIG. 17 shows that in some embodiments, an oscillator circuit having one or more features as described herein can be included in an electronic device.

FIG. 18 shows that in some embodiments, the electronic device of FIG. 17 can be a wireless device.

FIG. 19 shows that in some embodiments, the electronic device of FIG. 17 can be an IoT device.

### DETAILED DESCRIPTION OF SOME EMBODIMENTS

The headings provided herein, if any, are for convenience only and do not necessarily affect the scope or meaning of the claimed invention.

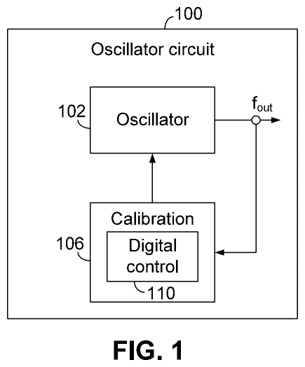

FIG. 1 depicts an oscillator circuit 100 configured to provide an output signal having an output frequency fₒᵤₜ. Such an output can be utilized in many electronic applications, and non-limiting examples of such electronic applications are described herein.

In some embodiments, the oscillator circuit 100 can include an oscillator 102 configured to provide the output signal with the output frequency fₒᵤₜ. For the purpose of description, it will be understood that the oscillator block indicated as 102 can include an oscillation source which is integrated as part of, external to, or some combination thereof, the block 102. In the various examples described herein, a crystal oscillator is utilized as such an oscillation source; however, it will be understood that one or more features of the present disclosure can also be implemented with other types of oscillation sources.

FIG. 1 shows that in some embodiments, the oscillator circuit 100 can further include a calibration circuit collectively indicated as 106. As described herein, such a calibration circuit can be configured to provide an injection signal to the oscillator 102 such that the output frequency fₒᵤₜ is established in a fast manner with power efficiency. In some embodiments, such an injection signal can include a delta-sigma modulated signal that is based on a digital control word. As described herein, such an injection signal can include a waveform that has one or more components of frequency(ies) set by the digital control word. As also described herein, use of such an injection signal where the frequency of injection is proportional to the output signal frequency fₒᵤₜ, a fast startup of the oscillator circuit 100 can be achieved. Examples related to the foregoing digital control word are described herein in greater detail.

In some embodiments, the calibration circuit 106 can include a digital control block collectively indicated as 110. Various examples, including advantageous features, related to such digital control functionality are described herein in greater detail.

In many electronic applications, oscillator circuits having one or more performance features are desirable. For example, fast startup performance is an important feature for communication systems that utilize aggressive dynamic power management through heavy-duty cycling. Described herein are various examples of an oscillator circuit utilizing a crystal oscillator (XO) that provides, among others, such a fast startup performance. While such examples are described in the example context of a crystal oscillator, it will be understood that one or more features of the present disclosure can also be implemented with other types of oscillators.

In some embodiments, and as described herein by way of an example, an integrated solution in 65-nm CMOS occupying a core area of approximately 0.209 mm² utilizing a single crystal oscillator (XO) with delta-sigma modulator (DSM)-based calibration. To provide power efficiency (e.g., extending of battery life) through efficient duty-cycle operation, the DSM-based injection technique as described herein is shown to significantly reduce startup time (Tₛₜₐᵣₜ) to, for example, 22 μs which is a 65.9× reduction in Tₛₜₐᵣₜ at start-up energy (Eₛₜₐᵣₜ) of 72.9 nJ which is a 7.7× reduction in start-up energy.

In some embodiments, and as described herein by way of examples, oscillators such as crystal oscillators are utilized in electronic devices such as internet-of-things (IoT) devices. Although various examples are described in the example context of a IoT devices, it will be understood that one or more features of the present disclosure can also be implemented with other types of electronic devices.

It is noted that crystal oscillators (XOs) are important components in IoT devices, supplying precise and stable clock signals for high-frequency signal synthesis and accurate timekeeping. Fast-start-up XO is important for ultra-low-power IoT devices. In many IoT networks, duty cycling is a notable technique for conserving energy. However, due to high-quality factors (e.g., Q>60 k) of crystal oscillators, their settling time can be relatively long, making them power-hungry and unsuitable for IoT devices without modifications. Therefore, a technique for quick startup of crystal oscillators is desirable.

It is noted that due to the high-quality factors associated with crystal oscillators, a conventional crystal oscillator's startup time (T_{START}) is typically quite long (e.g., 1 to 20 ms), which can dominate the length of an awakened duration expressed as follows:

$${T}_{S T A R T} = \frac{2 Q}{{ω}_{M}} ( \frac{1}{\frac{\vert {R}_{N} \vert}{{R}_{M}} - 1} ) [ ln \vert {i}_{M , S S} \vert - ln \vert {i}_{M} ( 0 ) \vert ] \qquad ( 1 )$$

where R_{N} and R_{M} are the negative and motional resistance, respectively, of gₘ cell and crystal, ω_{M} is the fundamental oscillation frequency of the XO, and i_{M,SS} and i_{M}(0) are the steady-state motional inductor current of the crystal and the magnitude of the initial motional branch current, respectively.

Shorter XO startup times with low startup energy are important metrics in electronic applications. Techniques related to faster startups are described in K. M. Megawer et al., “18.5 a 54 MHz crystal oscillator with 30× start-up time reduction using 2-step injection in 65 nm CMOS,” in IEEE Intl. Solid-State Cir. Conf. (ISSCC), 2019, pp. 302-304, and J. Jung et al., “A single-crystal-oscillator-based clock-management IC with 18× start-up time reduction and 0.68 ppm/° C. duty-cycled machine-learning-based RCO calibration,” in IEEE Intl. Solid-State Cir. Conf. (ISSCC), vol. 65, 2022, pp. 58-60. Such techniques utilize a three-step injection process, where the first two steps are to inject a crystal to get a small amplitude oscillation and then align an RC oscillator frequency with the crystal frequency using a phase-locked loop (PLL). The third step is to quick-start the oscillation by injecting the crystal with the PLL-locked RC oscillator. The injection process involves a ring oscillator (RO) calibration step to inject with a less-than-10000 ppm frequency signal in the beginning and the PLL locking process in the second step; however, such a process extends the overall duration.

Another technique related to a faster startup is described in M. Ding et al., “5.3 A 95 μw 24 MHz digitally controlled crystal oscillator for IoT applications with 36 nJ start-up energy and >13× start-up time reduction using a fully-autonomous dynamically-adjusted load,” in IEEE Intl. Solid-State Cir. Conf. (ISSCC), 2017, pp. 90-91. In such a technique, load capacitance of a crystal is modulated to fast start the motional current of the crystal. In the absence of a start-up injection, the start-up time is considerably longer.

Yet another technique related to a faster startup is described in D. Griffith, J. Murdock, and P. T. Roine, “5.9 A 24 MHz crystal oscillator with robust fast start-up using dithered injection,” in IEEE Intl. Solid-State Cir. Conf. (ISSCC), 2016, pp. 104-105. In such a technique, a wide variation in injection signal frequency is introduced. Instead of maintaining a fixed injection frequency from an RC oscillator, a dithering process involves continuously modulating the RC oscillator's frequency at a much lower frequency than the crystal oscillation frequency. However, the required calibration for the RC oscillator and the lower injection signal strength limits the start-up time.

Yet another technique related to a faster startup is described in H. Luo et al., “A fast startup crystal oscillator using impedance guided chirp injection in 22 nm FinFET CMOS,” IEEE J. Solid-State Cir. (JSSC), vol. 57, no. 3, pp. 688-697, 2022. Such an impedance guided chirp injection (IGCI) technique accelerates XO start-up by injecting a chirp-based clock with time-varying frequencies near the XO's intrinsic frequency while tracking the impedance minima at the crystal output. However, the multi-step tracking and the susceptibility to PVT variations limits the start-up time.

Yet another technique related to a faster startup is described in B. Verhoef, J. Prummel, W. Kruiskamp, and R. Post, “18.6 A 32 MHz crystal oscillator with fast start-up using synchronized signal injection,” in IEEE Intl. Solid-State Cir. Conf. (ISSCC), 2019, pp. 304-305. In such a technique, energy injection process is periodically stopped for phase alignment between the injected clock and XO's intrinsic oscillation.

It is noted that in the last two examples, the injection process needs to be stopped for frequency detection or phase alignment, inevitably slowing down the XOs' start-up processes.

In some implementations, the present disclosure includes a fast startup process that utilizes a robust delta-sigma modulator (DSM)-based single-step injection technique that provides a fast startup time of a crystal such as a 40 MHz crystal. In some embodiments, such an approach is compatible with a wide range (e.g., DC to 100 MHz) of crystal frequencies and incorporates a calibrated DSM input frequency control word (FCW) at each duty cycle interval. Fabricated using an example 65-nm CMOS process, a prototype crystal oscillator having the foregoing features demonstrates a startup time of just 22 μs, representing a reduction of over 65.9× compared to a conventional 40 MHz XO without injection.

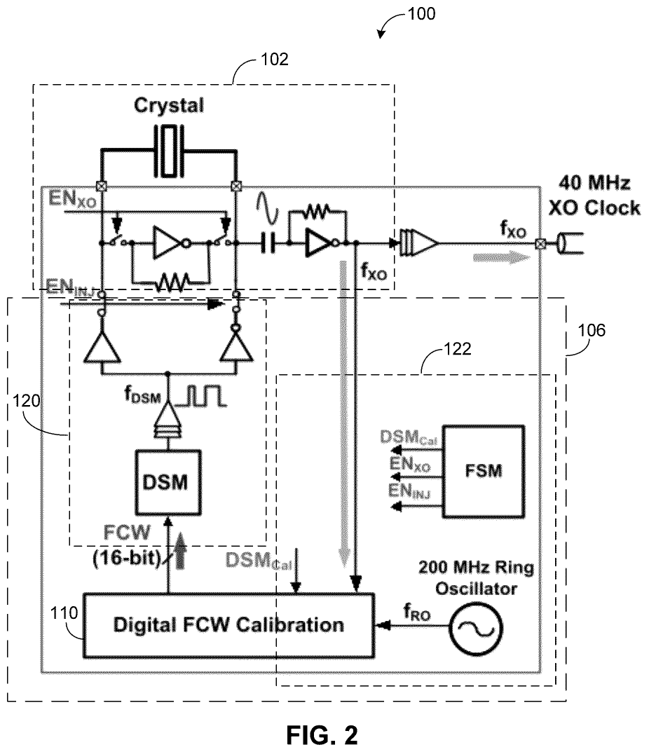

FIG. 2 shows an architecture 100 that can be implemented as a more specific example of the oscillator circuit 100 of FIG. 1 to include the foregoing fast startup functionality. In FIG. 2, the architecture 100 is shown to include a DSM-based injection block 120 and a digital FCW calibration block 110. In some embodiments, the DSM-based injection block 120 and the digital FCW calibration block 110 can be parts of and/or be configured to support the digital control functionality 110 of the calibration circuit 106 of FIG. 1.

FIG. 2 shows that in some embodiments, the calibration circuit 106 can further include a feedback calibration block 122 configured to obtain a frequency control word (FCW) as a function of the output signal frequency fₒᵤₜ. As described herein, generation of such an FCW can include use of a second oscillation input such as a ring oscillator input having a frequency f_{RO}.

In some embodiments, and as described herein, an FCW generated by the feedback calibration block 122 can be based on change(s) in some or all of process, voltage and temperature resulting from shift(s) in one or more operating and/or environmental parameters associated with the oscillator circuit 100.

In the example of FIG. 2, a crystal oscillator (XO) 102 is shown to include a crystal coupled to input and output of an inverting op-amp. More particularly, the input of the op-amp is shown to be coupled to one side of the crystal through a switch, and the output of the op-amp is shown to be coupled to the other side of the crystal through a switch. Operation of the input-side and output-side switches are shown to be controlled by an enable signal EN_{XO}.

In the example of FIG. 2, the output of the inverting op-amp is shown to be coupled to another inverting op-amp through a DC-block capacitance, such that an output of the second op-amp provides an output frequency f_{XO}.

The output signal having the output frequency f_{XO} is shown to be sampled by feedback calibration block 122 to allow generation of a frequency control word (FCW). Such an FCW (e.g., 16-bit word) is shown to be generated by the digital FCW calibration block 110 and provided to a delta-sigma modulator (DSM) to generate a control signal f_{DSM}. The control signal f_{DSM} is shown to be provided to the input side of the inverting op-amp through a non-inverting logic gate, a first switch, and the input-side switch (described above and controlled by the enable signal EN_{XO}), and to the output side of the inverting op-amp through an inverting logic gate, a second switch, and the output-side switch (described above and controlled by the enable signal EN_{XO}). Operation of the foregoing first and second switches at the outputs of the non-inverting and inverting logic gates are shown to be controlled by an enable signal EN_{INJ}.

In the example of FIG. 2, operation of the digital FCW calibration block 110 is shown to be controlled by a control signal DSM_{Cal}. In some embodiments, such a control signal, as well as the XO injection enable signal EN_{XO} and the DSM injection enable signal EN_{INJ} can be provided by a finite state machine (FSM).

In the example of FIG. 2, an oscillator input is shown to be provided to the digital FCW calibration block 110. For example, a ring oscillator (RO) is shown to provide a signal having an example frequency of f_{RO}=200 MHz to the digital FCW calibration block 110. Such an RO signal can be utilized to generate an FCW as described herein.

In some embodiments, upon powering on of a chip having the architecture 100, the XO 102 can start without any energy injection, and such an XO start is depicted in FIG. 4 at time “Power on.” Referring to FIGS. 2 and 4, the digital FCW calibrator is shown to start calibrating the FCW once the XO reaches full swing, and this FCW is used to inject energy in the next duty cycle using the DSM. The digital FCW calibrator is turned ON periodically during each duty cycle to calibrate the FCW and shut down after the calibration is done.

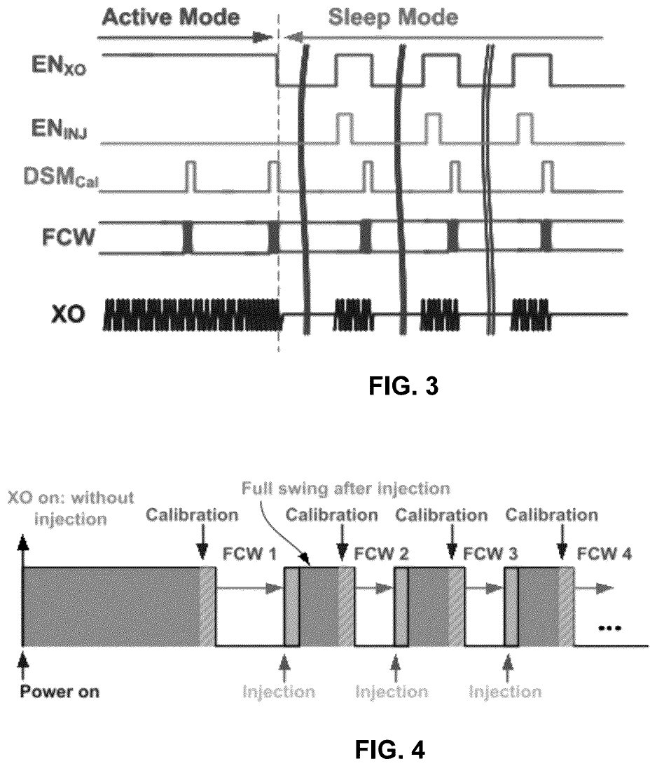

In some embodiments, the foregoing architecture 100 can support two operational modes: active and sleep modes, and various example timing diagrams are shown in FIG. 3. In the active mode, the XO remains powered ON continuously, and the FCW undergoes periodic calibration to provide desirable performance and a fast start-up in the beginning. In the sleep mode, both the XO and FCW are periodically powered ON and OFF to maintain calibration, with the XO featuring a fast-start mechanism during this mode. The XO startup circuit turns on by the EN_{XO} signal, which enables the gm circuit, and EN_{INJ} signal is used to start the injection process.

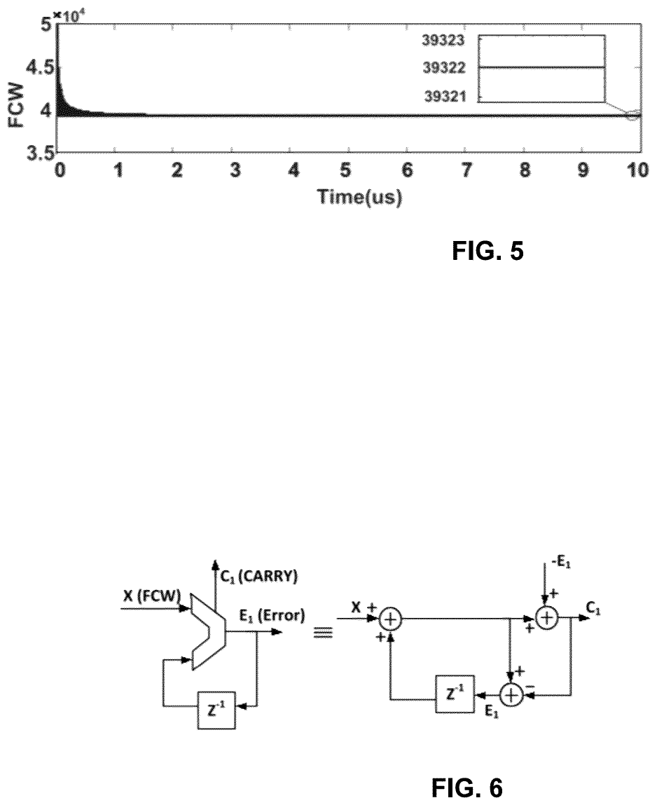

In the example of FIGS. 2 to 4, once the XO has full swing after the fast startup, the FCW can be re-calibrated, and it takes approximately 10 μs as shown in FIG. 5. The example 16-bit FCW can be calculated and stored in digital registers for the next duty cycle, and the FCW calibrator can be turned OFF to save power once the calibration is over. Such an operation can provide saving of a significant amount of power, thereby making the architecture 100 suitable for IoT ultra-low power applications.

FIG. 6 shows a first-order DSM configuration (on the left side) implemented with a digital accumulator and used in the digital calibration control architecture 100 of FIG. 2, and its corresponding equivalent error-feedback model in z-domain (on the right side).

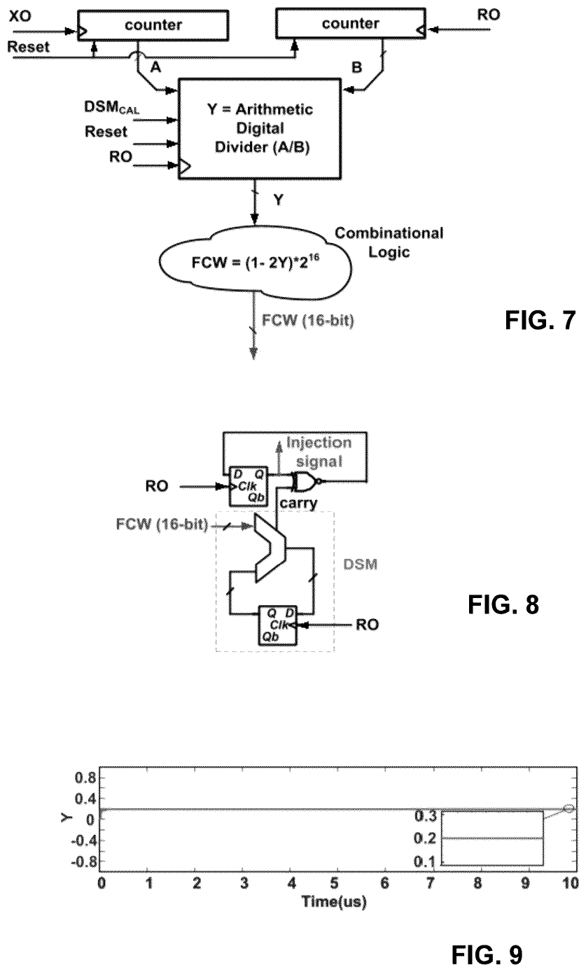

FIGS. 7 to 9 show various example diagrams for the DSM-based injection architecture 100 of FIG. 2. More particularly, FIG. 7 shows a block diagram of an FCW generator that can be implemented for the Digital FCW Calibration block of FIG. 2. It is noted that in FIG. 7, the XO output frequency fₒᵤₜ is shown to be measured by a counter. Such a measurement can be achieved by counting the number of edges during a selected time duration to obtain frequency information.

FIG. 8 shows an example of a DSM-based injection signal generator that can be implemented for the DSM block of FIG. 2. FIG. 9 shows a simulated output of an arithmetic divider of FIG. 7.

In some embodiments, the signal generator of FIG. 8 can include a 16-bit accumulator with the example 16-bit FCW input. The output of the accumulator is a carry signal that modulates a divider using an XNOR gate. This carry signal can alter the divider's output frequency, shifting it from DC up to half of, for example, a 200 MHz RO frequency (f_{RO}/2=100 MHz).

For any given FCW, the foregoing divider can produce a signal with a specific frequency determined by the equation:

$${f}_{INJ} = \frac{{f}_{R O}}{2} ( 1 - \frac{F C W}{{2}^{16}} ) \qquad ( 2 )$$

where f_{INJ} is the frequency of the DSM-controlled injection signal. For example, to generate a 40 MHz injection signal, the FCW can be 39322 (see FIG. 5). The digital FCW generator can precisely compute these FCW values during the preceding duty cycle.

In some embodiments, the FCW code generator of FIG. 7 can be activated during a calibration stage using a DSM_{CAL} signal. Such a generator block can include two 16-bit up counters. Two inputs of these counters can be provided from the 40 MHz XO and an on-chip 200 MHz RO. The ratio of the outputs of these up-counters, A and B, represents the ratio of the frequencies of the XO and RO.

In some embodiments, an FCW is calculated as follows in the FCW code generator of FIG. 7:

$$F C W = {2}^{16} ( 1 - 2 * \frac{{f}_{XO}}{{f}_{R O}} ) = {2}^{16} ( 1 - 2 * \frac{A}{B} ) = {2}^{16} ( 1 - 2 * Y ) . \qquad ( 3 )$$

As shown in FIG. 7, the ratio of the f_{XO} and f_{RO} can be generated using a digital unsigned arithmetic divider. Input values of the arithmetic divider can be sampled on the rising clock edge of the RO 200 MHz signal when the DSM_{CAL} signal is high to start the FCW calibration process. The divider remainder, Y, can be a 16-bit fractional number, with the quotient being discarded since its output is always zero. In an example, the arithmetic divider of FIG. 7 takes approximately 10 μs to generate a desired value as its output (Y), as depicted in FIG. 9.

Referring to the example of FIGS. 7 to 9, Y is calculated as 40 MHz/200 MHz=0.2, which the divider accurately produces. The remainder, Y, is then passed to the combinational logic, which computes the final FCW as follows:

$$F C W = {2}^{16} ( 1 - 2 * Y ) . \qquad ( 4 )$$

In some embodiments, the multiplication in the combinational logic can be achieved using binary left-shifting of the digital bits, and such an operation typically takes a fraction of a microsecond (e.g., due to gate delays of the combinational logic) to generate the final FCW. In some embodiments, the entire FCW code generation block can be implemented with digital standard cells and can be implemented using a place-and-route synthesis tool.

It is noted that due to the duty cycling process, the foregoing calibration can occur in every duty cycle with a very short interval, making temperature variations negligible. Additionally, since this FCW calibration is performed digitally, unlike the conventional energy injection techniques mentioned above, it is not affected by process or voltage variations. Such a feature makes it a highly efficient method for generating an energy injection signal.

As described herein, a DSM-based injection signal generation can produce signals ranging from DC up to half the ring oscillator frequency (e.g., f_{RO}/2=100 MHz). This capability allows the oscillator circuit as described herein to generate injection signals of any desired frequency within that range, making it suitable for use with a variety of oscillators such as XOs.

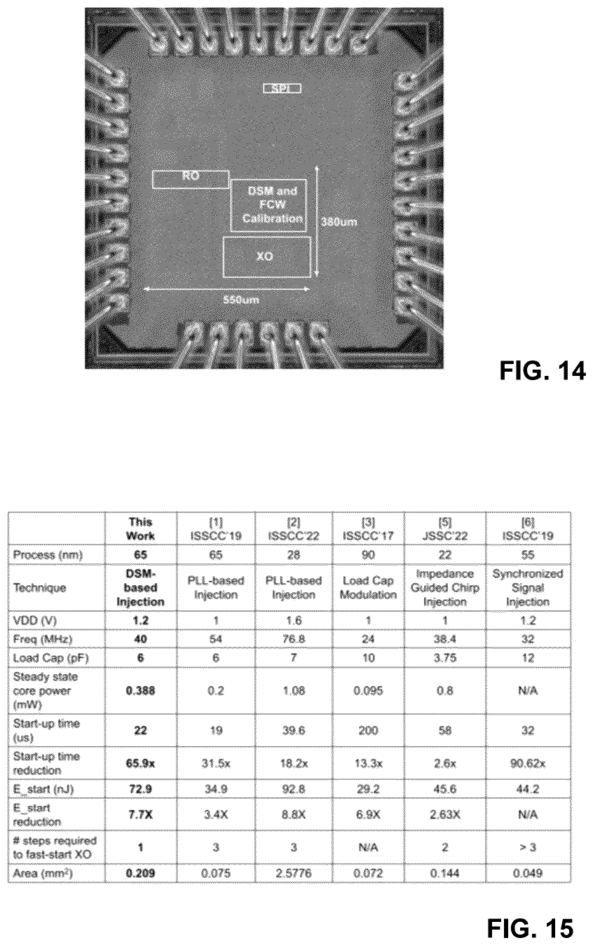

FIG. 14 shows a chip on which the architecture 100 of FIG. 2 was implemented. By way of examples, the architecture 100 having a fast startup functionality was implemented in a 65-nm CMOS process using a 40 MHz crystal with 6 pF on-chip load capacitance. Referring to the die photograph shown in FIG. 14, it is noted that the die has an active area of 0.209 mm2.

The measured XO's oscillation frequency is 40 MHz, and phase noise is-166 dBc/Hz at 1 MHz offset. FIG. 15 shows a table with various parameters and performance values in comparison with the other startup techniques mentioned above.

As described herein, it is noted that peak-to-peak swing is 1.0V, such that the architecture 100 of FIG. 2 as described herein is suitable for low-noise wireless applications including wireless protocols implemented in IoT devices.

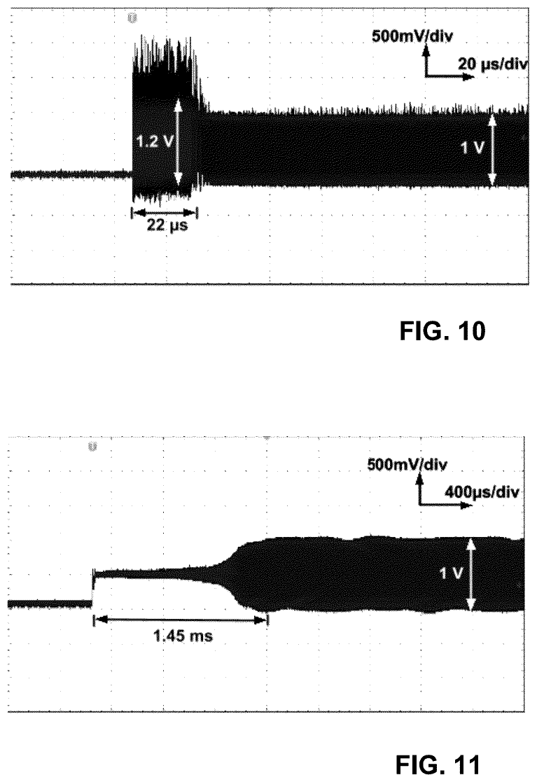

FIG. 11 shows a typical measured XO startup waveform with no injection. As expected, the startup time is long and is about 1.45 ms. In an example context of a start-up time being defined as a duration between powering up and when the XO amplitude settles within 95% of its final value, FIG. 10 shows a startup waveform achieved with the DSM-based injection technique as described herein, demonstrating that the reduced startup time to about 22 μs. Such a reduced startup time of 22 μs is a reduction by a factor of more than 65 when compared to the startup time of 1.45 ms in FIG. 11.

As described herein, a DSM-based injection signal is generated by the FCW calibrated in the previous duty cycle. The robustness of such a technique for temperature variations is measured, and the results are shown in FIG. 13. With startup time measurements being obtained across 20-85° C., it is noted that conventional XO takes 1.45 ms to 2.2 ms to start up, while the startup time with the DSM-based injection remains <27 μs across the entire temperature range (FIG. 13).

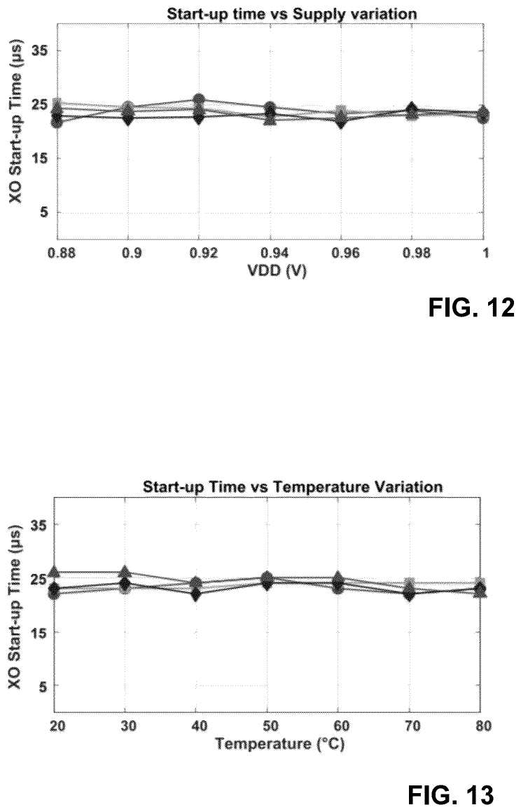

FIG. 12 shows that startup time across supply voltage variation is also shown under 25 μs from 0.88V to 1.0V range. As described herein, the example FCW calibration takes around 10 μs as shown in FIG. 5 and consumes 55.8 nJ of energy, whereas the injection takes 17.1 nJ of energy, consuming a total of 72.9 nJ of energy. Thus, one can see that the FCW calibration as described herein is suitable for low-power applications such as low-power battery-operated IoT systems.

In some embodiments, an FCW calibrator as described herein can be powered OFF after calibrating the 16-bit FCW to save energy. The RO can be turned ON during the injection phase to generate the 40 MHz injection signal. By way of examples, the steady-state oscillation is shown to consume 388 μW of power. Through injection, an energy reduction ratio of 7.7× is achieved. These results demonstrate that the DSM-based injection technique is a suitable solution for determining an optimal injection frequency in fast startup crystal oscillators, offering simplicity and low power consumption.

As described herein, a quick startup with XO can be achieved using a single-step DSM-based frequency injection, providing, for example, ultra-low injection times of only 22 μs simultaneously with startup energy reduction compared to conventional oscillator startup techniques. In some embodiments, the startup approach as described herein involves a single-step injection process, which is simpler than previous multi-step techniques.

The DSM-based injection is shown to greatly reduces XO startup time over a large frequency range (e.g., DC-100 MHz), demonstrating effectiveness even in low-phase noise situations with high-quality factor crystal resonators (e.g., Q>100 k) and 1V oscillator output swings. The example 40 MHz XO, utilizing a 65 nm CMOS, achieved 65.9× reduction in startup time and a 7.7× reduction in energy usage. These advancements markedly improve energy efficiency and system performance, thereby providing a desirable solution for electronic applications such as IoT applications where extended battery life and rapid operational response are important.

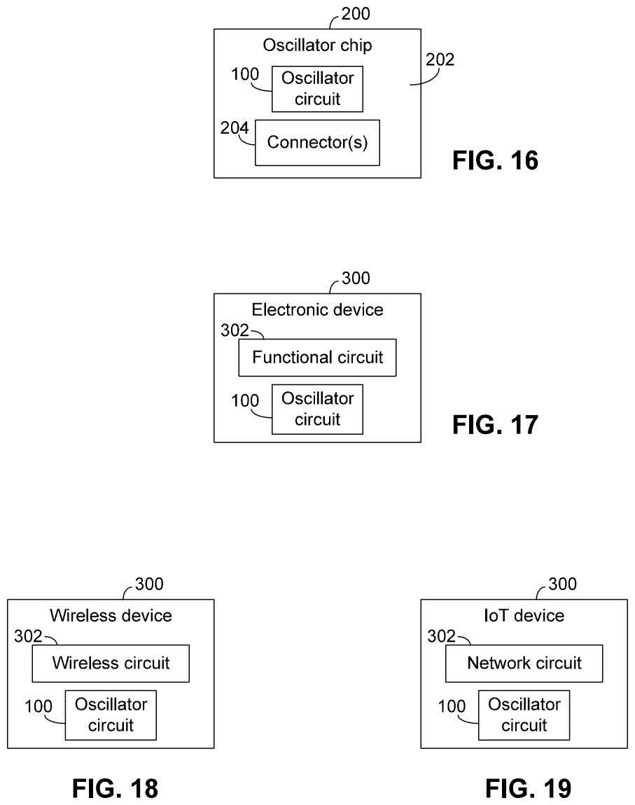

FIG. 16 shows that in some embodiments, an oscillator circuit 100 having one or more features as described herein can be implemented on a chip 200. In some embodiments, such a chip can be a semiconductor die, a packaged module, or some combination thereof.

For example, if the chip 200 is implemented as a semiconductor die, such a die can include a semiconductor substrate 202, and some or all of the oscillator circuit 100 can be implemented on the substrate 202.

In another example, if the chip 200 is implemented as a packaged module, such a module can include a packaging substrate 202, and some or all of the oscillator circuit 100 can be implemented on one or more die that is/are mounted on the packaging substrate 202.

In the example of FIG. 16, the chip 200 is also shown to include connector(s) 204 configured to provide connections for the oscillator circuit 100.

FIG. 17 shows that in some embodiments, an oscillator circuit 100 having one or more features as described herein can be included in an electronic device 300. Such an electronic device is shown to also include a functional circuit 302 that utilizes one or more functionalities provided by the oscillator circuit 100.

In the example of FIG. 17, in some embodiments, the oscillator circuit 100 can be implemented in the chip form as described in reference to FIG. 16.

FIG. 18 shows that in some embodiments, the electronic device of FIG. 17 can be a wireless device 300. Such a wireless device can include an oscillator circuit 100 having one or more features as described herein. Such an electronic device is shown to also include a functional circuit such as a wireless circuit 302 that utilizes one or more functionalities provided by the oscillator circuit 100.

FIG. 19 shows that in some embodiments, the electronic device of FIG. 17 can be an IoT device 300. Such an IoT device can include an oscillator circuit 100 having one or more features as described herein. Such an IoT device is shown to also include a functional circuit such as a network circuit 302 that utilizes one or more functionalities provided by the oscillator circuit 100.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An oscillator circuit comprising:
an oscillator configured to provide an output signal having a frequency based on a first oscillation signal having a frequency; and
a digital calibration circuit configured to inject a calibration signal to the oscillator during a startup process to allow the frequency of the output signal to be established at a desired frequency, the digital calibration circuit including a delta-sigma modulator configured to generate the calibration signal based on a digital control word.

2. The oscillator circuit of claim 1 wherein the digital calibration circuit includes a waveform that includes components of the desired frequency.

3. The oscillator circuit of claim 2 wherein the desired frequency includes the frequency of the first oscillation signal.

4. The oscillator circuit of claim 2 wherein the digital calibration circuit includes a digital word calibration block configured to generate an N-bit word as the digital control word based on the frequency of the first oscillation signal and a frequency of a second oscillation signal.

5. The oscillator circuit of claim 4 wherein the first oscillation signal is provided by a crystal oscillation source, and the second oscillation signal is provided by a ring oscillator.

6. The oscillator circuit of claim 4 wherein the frequency of the second oscillation signal is greater than the frequency of the first oscillation signal.

7. The oscillator circuit of claim 6 wherein the frequency of the second oscillation signal is M times the frequency of the first oscillation signal, M being a positive integer greater than 1.

8. The oscillator circuit of claim 4 wherein the N-bit word includes a 16-bit word.

9. The oscillator circuit of claim 4 wherein the delta-sigma modulator is configured to generate the calibration signal based on the N-bit word provided by the digital word calibration block.

10. The oscillator circuit of claim 9 further comprising a switch network configured allow the calibration signal to be injected to the oscillator in a selected manner.

11. The oscillator circuit of claim 4 further comprising a source of the first oscillation signal and/or a source of the second oscillation signal.

12. The oscillator circuit of claim 11 wherein each of the first oscillation signal and the second oscillation signal is a part of the oscillator circuit.

13. A method for operating an oscillator circuit, the method comprising:
receiving a first oscillation signal having a frequency;
operating an oscillator to provide an output signal having a frequency based on the first oscillation signal; and
providing a calibration signal to the oscillator during a startup of the oscillation circuit to allow the frequency of the output signal to be established at a desired frequency, the calibration signal including a delta-sigma modulated signal based on a digital word.

14. The method of claim 13 wherein the digital word includes an N-bit word based on the frequency of the first oscillation signal and a frequency of a second oscillation signal.

15. The method of claim 14 wherein the frequency of the second oscillation signal is greater than the frequency of the first oscillation signal.

16. The method of claim 15 wherein the frequency of the second oscillation signal is M times the frequency of the first oscillation signal, M being a positive integer greater than 1.

17. The method of claim 14 wherein the N-bit word includes a 16-bit word.

18. The method of claim 14 further comprising performing a switching operation to inject the calibration signal to the oscillator in a selected manner.

19. (canceled)

20. (canceled)

21. (canceled)

22. An electronic device comprising:
a functional circuit; and
an oscillator circuit configured to allow operation of the functional circuit, the oscillator circuit including an oscillator configured to provide an output signal having a frequency based on a first oscillation signal having a frequency, the oscillator circuit further including a digital calibration circuit configured to inject a calibration signal to the oscillator during a startup process to allow the frequency of the output signal to be established at a desired frequency, the digital calibration circuit including a delta-sigma modulator configured to generate the calibration signal based on a digital control word.

23. (canceled)

24. The electronic device of claim 22 wherein the electronic device is an IoT device.
